(19) United States
(12) Patent Application Publication
(10) Pub. No.: US 2013/0234304 A1
(43) Pub. Date: Sep. 12, 2013

(54) SEMICONDUCTOR DEVICE

(71) Applicant: RENESAS ELECTRONICS CORPORATION, Kawasaki-shi (JP)

(72) Inventor: Naoya Tamaki, Kanagawa (JP)

(73) Assignee: RENESAS ELECTRONICS CORPORATION, Kawasaki-shi (JP)

(21) Appl. No.: 13/783,243

(22) Filed: Mar. 2, 2013

(30) Foreign Application Priority Data
Mar. 8, 2012 (JP) 2012-051432

(51) Int. Cl. H01L 23/498; H01L 23/552

(52) U.S. Cl. CPC H01L 23/49827; H01L 23/552
USPC 257/659; 257/774

(57) ABSTRACT

When a material of an organic substrate is glass epoxy and a material of a semiconductor chip is silicon or gallium arsenide, a substrate warp sometimes occurs because of a difference between thermal expansion coefficients of the materials. The shape of the antenna formed on the organic substrate due to such a substrate warp, so that the characteristics of the antenna are sometimes shifted from desired values. An antenna is provided on the substrate on which a semiconductor chip is mounted, and is covered with a resin. The resin has enough hardness to suppress the warp caused by joining the semiconductor chip and the substrate and a transformation of the antenna. By changing a connection relation of adjustment vias after the manufacture of the semiconductor device, the characteristic of the antenna can be changed.

### CROSS REFERENCE

This application claims a priority on convention based on Japanese Patent Application No. JP 2012-051432. The disclosure thereof is incorporated herein by reference.

### TECHNICAL FIELD

The present invention relates to a semiconductor device, and especially relates to a semiconductor device including an antenna.

### BACKGROUND ART

A wireless communication system using a magnetically coupled antenna is known. In this wireless communication system, a mobile terminal having a magnetically coupled antenna is faced to a similar type of mobile terminal or to a fixed terminal so as to bring into contact with it or bring the mobile terminal close to it, to allow a non-contact communication. In such a wireless communication system, basically, communication possible distance and direction are strongly restricted based on a shape of the magnetically coupled antenna.

Specifically, a planar loop antenna is generally used as a magnetically coupled antenna, and the wireless communication is performed basically in a direction orthogonal to the planar surface of the antenna according to a directivity of the loop antenna. Also, the intensity of magnetic field in the wireless communication using the loop antenna is proportional to an area of the loop antenna, and accordingly it is required to ensure a size of the plane orthogonal to a communication direction of the mobile terminal and the like. Moreover, the intensity of magnetic field in the wireless communication using the magnetically coupled antenna is inversely proportional to the cube of a distance, and accordingly the wireless communication is performed basically in a very short distance.

There is a need for a wireless communication system that can perform a high speed and accurate transmission without the above-mentioned restriction. Especially, in case of using a high frequency band such as a gigahertz band, it is important that an antenna having desired antenna characteristics can be obtained.

In order to satisfy this need, there is a semiconductor device mounting an antenna as a conductor pattern formed on an organic substrate, and an antenna control circuit formed on the organic substrate, in addition to a semiconductor chip. In the semiconductor device, a size of the wireless communication system can be totally reduced by unifying the antenna and the antenna control circuit.

FIG. 1 is a cross sectional view showing a configuration of a millimeter wave detector 100 disclosed in Patent Literature 1 (JP H08-56113A). The configuration of the millimeter wave detector 100 of FIG. 1 will be described. The millimeter wave detector 100 includes a first semiconductor substrate 101, a ground conductor film 102, a dielectric film 103, a planar antenna 104, a second semiconductor substrate 105, bumps 106, and microstrip lines 107. The second semiconductor substrate 105 includes a signal detecting circuit or a signal generating circuit.

A connection relation between the components of the millimeter wave detector 100 of FIG. 1 will be described. The first semiconductor substrate 101, the ground conductor film 102, and the dielectric film 103 are laminated in this order from the bottom. The planar antenna 104 and the microstrip lines 107 are provided on the dielectric film 103. The second semiconductor substrate 105 is connected to upper surfaces of the microstrip lines 107 through the bumps 106. The second semiconductor substrate 105 and the planar antenna 104 are connected through the microstrip lines 107.

An operation of the millimeter wave detector 100 of FIG. 1 will be described. The microstrip lines 107 supply power to the planar antenna 104. The signal detecting circuit detects a signal that is received by the planar antenna 104. The signal generating circuit generates a signal that is transmitted from the planar antenna 104.

In relation to the above description, Patent Literature 2 (JP 2002-290141A) discloses a surface-mounted antenna. The surface-mounted antenna is characterized by including a base substrate, a radiation electrode, a ground (GND) electrode, a power supply electrode, a short-circuit electrode, and a resistance element. Here, the base substrate is composed of a dielectric substance or a magnetic substance. The radiation electrode is provided on one surface of the base substrate. The ground electrode is provided on a surface opposed to the one surface. The power supply electrode is connected to the radiation electrode. The short-circuit electrode short-circuits the radiation electrode and the ground electrode. The resistance element is connected to the radiation electrode at one end, and is connected to the ground electrode at the other end.

In addition, Patent Literature 3 (JP 2005-229499A) discloses a multi-band antenna device. The multi-band antenna device is characterized by including a plurality of antenna elements; an antenna switching section; a resonating operation adjusting section, and a band selecting section. Here, the plurality of antenna elements correspond to a plurality of frequency bands. The antenna switching section switches connection between input/output ports of the antenna device and the plurality of antenna elements so that the connection corresponds to a selected frequency band. The resonating operation adjusting section is connected to each of the plurality of antenna elements to adjust a resonating operation of each of the antenna elements. The band selecting section controls the resonating operation adjusting section and the antenna switching section in response to the selected frequency band.

### CITATION LIST

[Patent Literature 1] JP H08-56113A
[Patent Literature 2] JP 2002-290141A
[Patent Literature 3] JP 2005-229499A

### SUMMARY OF THE INVENTION

The inventor of the present application found that when a material of an organic substrate is glass epoxy and a material of a semiconductor chip is silicon or gallium arsenide, a substrate warp sometimes occurs because of a difference between both of the materials in thermal expansion coefficient. The inventor further found that the shape of the antenna formed on the organic substrate is changed due to such a substrate warp, so that the characteristics of the antenna had sometimes shifted from desired values.

Especially, when such a semiconductor device is connected with an external substrate such as a motherboard through an external terminal formed on the underside of the substrate, further attention should be paid. There is a case that the characteristics of the antenna formed in the semiconductor device are shifted from desired values, due to a difference between the external substrate and the substrate in the thermal expansion coefficient and a warp of the external substrate.

The semiconductor device of the present invention is provided with a semiconductor chip, a substrate, an antenna and resin. Here, the semiconductor chip is mounted on the substrate. The antenna is formed on the substrate and radiates a signal outputted from the semiconductor chip. The resin covers an antenna. The substrate has a mounting section provided to be mounted on another substrate.

According to the semiconductor device of the present invention, the semiconductor chip is mounted on a conductor layer on the surface side of a laminate substrate which uses a dielectric layer formed of resin, and also a patch antenna is formed. The patch antenna, the dielectric layer and a ground plane are laminated.

### BRIEF DESCRIPTION OF DRAWINGS

FIG. 1 is a cross sectional view showing a configuration of a conventional millimeter wave detector;

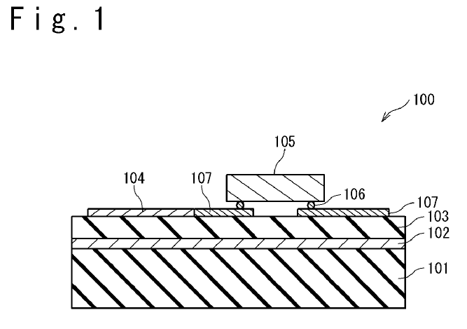

FIG. 2A is a plan view showing a configuration of a semiconductor device according to a first embodiment of the present invention;

FIG. 2B is a cross sectional view of the semiconductor device according to the first embodiment of the present invention along the line 2B-2B in FIG. 2A;

FIG. 2C is a view partially showing a position relation between a patch antenna and a semiconductor chip according to the first embodiment of the present invention, and showing an example of a distribution of voltage standing wave obtained by supplying power to the patch antenna;

FIG. 2D is a cross sectional view showing the semiconductor device according to the first embodiment of the present invention along the line 2B-2B when a shield is used;

FIG. 3A is a plan view showing a semiconductor device according to a second embodiment of the present invention;

FIG. 3B is a cross sectional view showing the semiconductor device according to the second embodiment of the present invention along the section line 3B-3B in FIG. 3A;

FIG. 4A is a plan view showing a configuration of the semiconductor device according to a third embodiment of the present invention;

FIG. 4B is a cross sectional view showing the configuration of the semiconductor device according to the third embodiment of the present invention along the line 4B-4B in FIG. 4A;

FIG. 5A is a plan view showing a first configuration of the semiconductor device according to a fourth embodiment of the present invention;

FIG. 5B is a cross sectional view showing a first configuration of the semiconductor device according to the fourth embodiment of the present invention along the line 5B-5B in FIG. 5A;

FIG. 5C is a plan view partially showing a second configuration of the semiconductor device according to the fourth embodiment of the present invention;

FIG. 5D is a cross sectional view partially showing the second configuration of the semiconductor device according to the fourth embodiment of the present invention along the line 5D-5D in FIG. 5C;

FIG. 5E is an enlarged view when the cross sectional view along the line 5D-5D in FIG. 5C showing the second configuration of a laminate substrate according to the fourth embodiment of the present invention is enlarged in a thickness direction;

FIG. 5F is a diagram partially showing a position relation between a patch antenna and a semiconductor chip according to the second configuration of the fourth embodiment of the present invention and showing an example of a distribution of voltage standing wave obtained by supplying power to the patch antenna;

FIG. 6A is a plan view showing a configuration of the semiconductor device according to a fifth embodiment of the present invention;

FIG. 6B is a plan view partially showing a configuration of a system board according to the fifth embodiment of the present invention;

FIG. 6C is a cross sectional view showing the configuration of the semiconductor device and a system board according to the fifth embodiment of the present invention along the line 6C-6C in FIG. 6A and FIG. 6B;

FIG. 6D is an enlarged view when the cross sectional view of a laminate substrate and a system board according to the fifth embodiment of the present invention is enlarged in a thickness direction;

FIG. 7A is a plan view showing a configuration of the semiconductor device according to a sixth embodiment of the present invention;

FIG. 7B is a cross sectional view showing the configuration of the semiconductor device according to the sixth embodiment of the present invention along the line 7B-7B in FIG. 7A;

FIG. 7C is an enlarged view when the cross sectional view along the line 7B-7B in FIG. 7A showing a configuration of a laminate substrate according to the sixth embodiment of the present invention is enlarged in a thickness direction;

FIG. 8A is a plan view showing a configuration of the semiconductor device according to a seventh embodiment of the present invention;

FIG. 8B is a cross sectional view showing the configuration of the semiconductor device according to the seventh embodiment of the present invention along the line 8B-8B in FIG. 8A;

FIG. 8C is an enlarged view when the cross sectional view along the line 8B-8B in FIG. 8A showing a configuration of a laminate substrate according to the seventh embodiment of the present invention is enlarged in a thickness direction;

FIG. 9A is a plan view showing a configuration of the semiconductor device according to an eighth embodiment of the present invention; and

FIG. 9B is a cross sectional view showing the configuration of the semiconductor device according to the eighth embodiment of the present invention along the line 9B-9B in FIG. 9A.

### DESCRIPTION OF EMBODIMENTS

Hereinafter, a semiconductor device according to embodiments of the present invention will be described in detail with reference to the attached drawings.

### First Embodiment

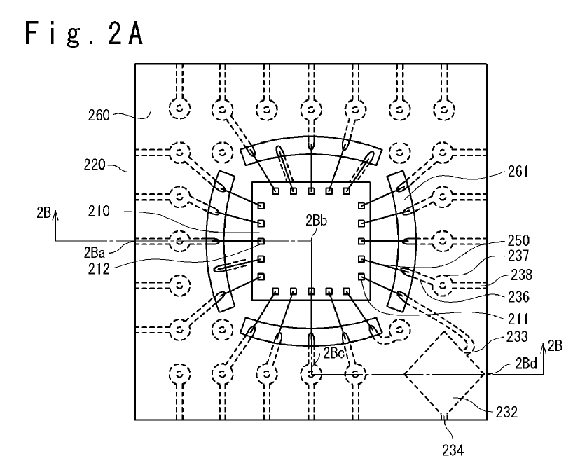

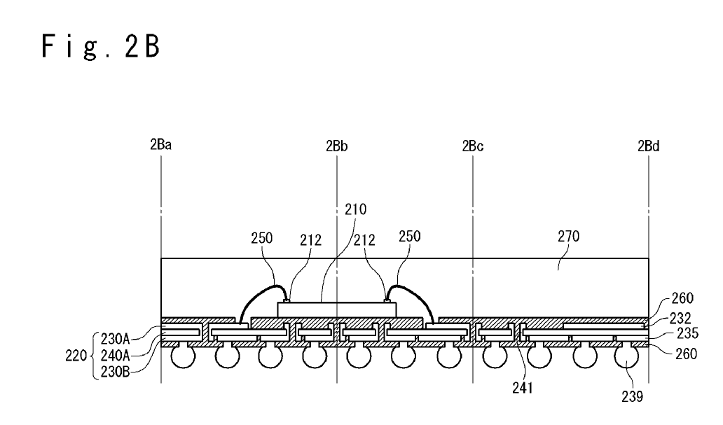

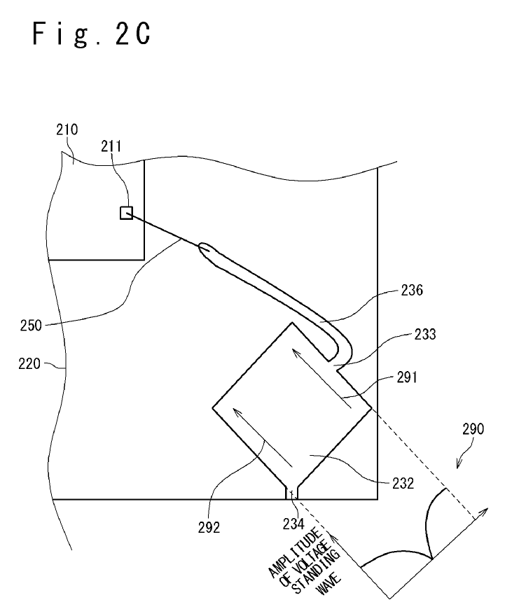

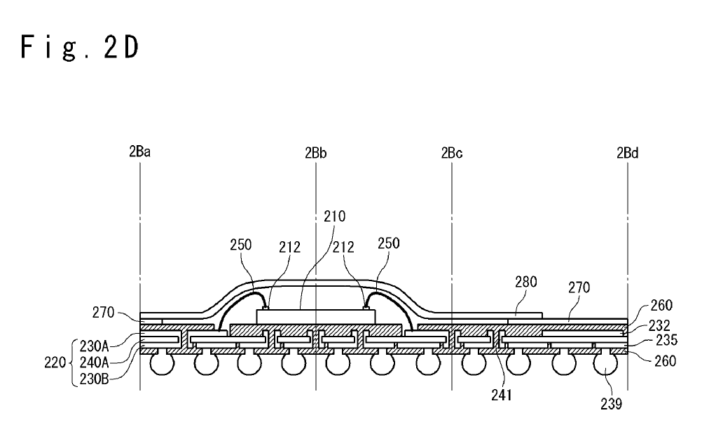

FIG. 2A is a plan view showing a configuration of a semiconductor device according to a first embodiment of the present invention. FIG. 2B is a cross sectional view of the semiconductor device according to the first embodiment of the present invention along a line 2B-2B in FIG. 2A. Points 2Ba, 2Bb, 2Bc, and 2Bd on the line 2B-2B shown in FIG. 2A correspond to division lines 2Ba, 2Bb, 2Bc, and 2Bd of the cross sectional view shown in FIG. 2B, respectively. Meanwhile, a mold resin 270 to be described below is omitted in the plan view of FIG. 2A and a layer of a solder resist 260 to be described below is made transmissive.

Components of the semiconductor device shown in FIGS. 2A and 2B will be described. The semiconductor device according to the present embodiment includes a semiconductor chip 210, a laminate substrate 220, bonding wires 250 and the mold resin 270. The semiconductor chip 210 includes signal pads 211 and ground pads 212.

The laminate substrate 220 includes conductor layers 230A and 230B, an insulator layer 240A, vias 241, ball lands 239, and solder resist 260. Here, a case where the laminate substrate 220 includes the two conductor layers 230A and 230B and the insulator layer 240A will be described. The first conductor layer 230A includes lead lines 236, lands 237, a power supply point 233, a patch antenna 232, plated lines 234 and 238, and the solder resist 260. The second conductor layer 230B includes various types of wirings 235, the ball lands 239, and the solder resist 260.

Here, it is supposed that the insulator layer 240A is formed of a resin 243 such as FR4. Generally, unlike the FR4 and the solder resist 260, the mold resin 270 is featured by including metal oxide such as silicon dioxide of 85% or more in weight % as a filler. The mold resin 270 has sufficient hardness, and can suppress a warp resulting from a junction between the semiconductor chip 210 and the laminate substrate 220, and a deformation of the antenna, by covering at least a part of the semiconductor chip 210, the laminate substrate 220, and the patch antenna 232. In addition, the mold resin 270 can have a larger deformation resistance, when being formed to have a sufficient thickness, as in case of being thicker than the laminate substrate 220.

It should be noted that the total number of components and the features of each of these components are only an example, and accordingly the present invention is not limited to this example.

A connection relation and a position relation between the components of the semiconductor device 200 shown in FIGS. 2A and 2B will be described. The first conductor layer 230A, the insulator layer 240A, and the second conductor layer 230B are laminated in this order from the top.

The surface of the first conductor layer 230A is covered with the solder resist 260 with the exception of an opening portion 261 and the like provided in a part of the surface. In addition, the surface of the second conductor layer 230B is also covered with the solder resist 260 with the exception of a connecting portion and the like of the ball land 239. Further, the solder resist 260 may be filled in the inside of the vias 241.

In the first conductor layer 230A, one-side end portions of a part of the lead lines 236 is exposed from the opening portion 261 of the solder resist 260. The exposed portions of the lead lines 236 are connected to the signal pads 211 or the ground pads 212 in the semiconductor chip 210 by the bonding wires 250.

The vias 241 are formed to partially or completely pass through the laminate substrate 220 in a thickness direction. Each of the vias 241 is connected to the first and second conductor layers 230A and 230B at the respective both ends, in order to electrically connect the first and second conductor layers 230A and 230B each other across the insulator layer 240A.

The semiconductor chip 210 is mounted on the first conductor layer 230A. The signal pad 211 of the semiconductor chip 210 is electrically connected to the power supply point 233 of the patch antenna 232 through the bonding wire 250 and the lead line 236. The ground pad 212 of the semiconductor chip 210 is electrically connected to the wiring 235 through another bonding wire 250, another lead line 236 and a via 241.

It is preferred that the patch antenna 232 is arranged at a corner portion of the first conductor layer 230A. This is because an area sufficient to some extent can be easily secured in the first conductor layer 230A where a large number of the lead lines 236 are arranged around the semiconductor chip 210. In addition, it is preferred that the patch antenna 232 is arranged in such a manner that a direction of the radiation pattern can be a direction orthogonal to a direction to the semiconductor chip 210 so that the direction to the semiconductor chip 210 can be avoided. This is because the existence of the semiconductor chip 210 does not hinder the radiation from the patch antenna 232. For example, as shown in FIG. 2A, when the patch antenna 232 has a rectangular shape, the semiconductor chip 210 and the laminate substrate 220 have a square shape, and the semiconductor chip 210 is arranged at a center of the laminate substrate 220, a position relation is preferred in which the rectangular shape of the patch antenna 232 is divided in a line-symmetry with a diagonal line of the laminate substrate 220.

Because the patch antenna 232 has a relatively large area, it would be necessary to provide the plated line 234 directly connected to the patch antenna 232, when the patch antenna 232 is arranged on a corner portion of the laminate substrate 220. In this case, it is preferred that easiness of the calculation of property based on the shape of the patch antenna 232 is considered, so that the plated line 234 is arranged on a corner portion of the patch antenna 232.

Here, a region immediately above and around the patch antenna 232 may be configured so that the solder resist 260 is omitted and the mold resin 270 directly protects the patch antenna 232. A change to the configuration can be achieved only by arbitrarily changing the shape of a mask used in forming the solder resist 260. As a result, the manufacturing variations of antenna characteristics of the patch antenna 232 can be suppressed. This is because the thickness of the mold resin is uniquely determined, while manufacturing variations of the film thickness of the solder resist is wide. In any case, so-called wavelength shortening effect can be obtained by covering the patch antenna 232 with the mold resin 270, the solder resist 260, and the like each having a dielectric constant larger than that of the air. That is, since an effective dielectric constant around the patch antenna 232 becomes larger than the effective dielectric constant when the patch antenna 232 is exposed to the air, an effective wavelength is shortened, and the size of the patch antenna 232 can be reduced.

An operation of the semiconductor device shown in FIGS. 2A and 2B will be described. FIG. 2C is a diagram partially showing a position relation between the patch antenna 232 and the semiconductor chip 210 according to the first embodiment of the present invention, and shows an example of a voltage standing wave distribution obtained by supplying power to the patch antenna 232. FIG. 2C shows a position relation among the semiconductor chip 210, the signal pad 211, the bonding wire 250, the lead line 236, the power supply point 233, the patch antenna 232, the plated line 234, a first magnetic current 291, a second magnetic current 292, and the laminate substrate 220. FIG. 2C further shows a graph 290 showing amplitude of a voltage standing wave distributed in a width direction of the patch antenna 232.

When electric power is supplied to the patch antenna 232 arranged as shown in FIGS. 2A to 2C, the magnetic current and the voltage standing wave distribution shown in FIG. 2C are obtained. The first and second magnetic currents 291 and 292 in FIG. 2C appear along two sides extending in a direction to the semiconductor chip 210 in the rectangular patch antenna 232. In addition, the amplitude of the voltage standing wave in the graph 290 of FIG. 2C takes the maximum value at the two sides at which the magnetic currents 291 and 292 appear, and takes the minimum value in the intermediate region between the sides. This means that a radiation pattern spreading in direction in which the radiation is not blocked by the semiconductor chip 210 can be obtained.

After preparation of a plurality of semiconductor devices according to the present embodiment, the semiconductor devices are arranged in a suitable position relation for the radiation pattern of FIG. 2C, and a wireless communication between the semiconductor devices can be carried out through the patch antenna 232.

It should be noted that it is preferred that a ground plane is formed in a portion of the second conductor layer 230B corresponding to the back surface of the patch antenna 232. Additionally, instead of the patch antenna 232, antennas having various shapes and being able to be formed in the first conductor layer 230A, such as a dipole antenna, a monopole antenna, a loop antenna, and a log periodic antenna can be used. In this case, not only the ground plane, but wirings necessary for forming the above-mentioned types of antennas may be formed in the portions of the second conductor layer 230B corresponding to the back surface of the antenna, and vias through which the above-mentioned antenna and wirings are arbitrarily connected may be provided to pass through the insulator layer 240A.

In addition, instead of the mold resin 270, a shield for protecting the semiconductor chip 210 may be employed. FIG. 2D is a cross sectional view of the semiconductor device according to the first embodiment of the present invention in which the shield is employed. The cross section is along the line 2B-2B. The semiconductor device shown in FIG. 2D is equivalent to the semiconductor device shown in FIG. 2B in which the mold resin 270 is replaced with a shield 280. However, since it is not preferred that the patch antenna 232 is entirely covered with the shield, it is supposed that a portion of the patch antenna 232 is sufficiently protected by the mold resin 270. Moreover, a space between the shield 280 and the first conductor layer 230A may be filled with the mold resin 270. It should be noted that other components of the semiconductor device shown in FIG. 2D are the same as those shown in FIG. 2B, and accordingly further detailed description will be omitted.

### Second Embodiment

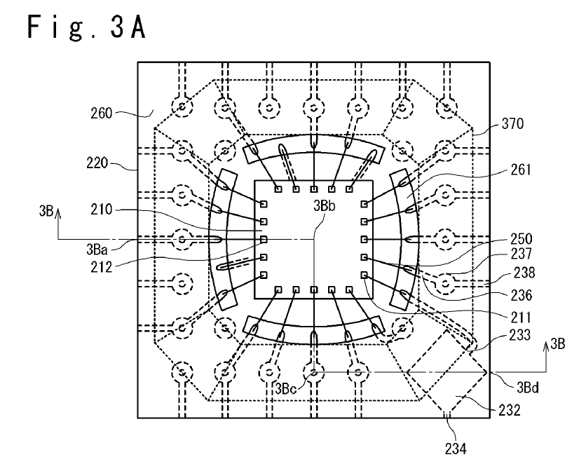

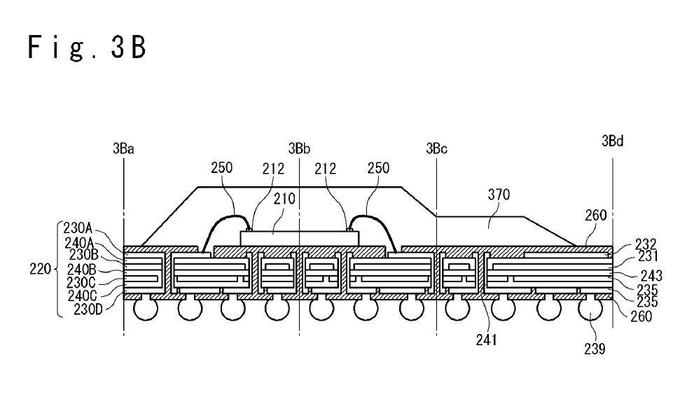

FIG. 3A is a plan view showing a configuration of the semiconductor device according to a second embodiment of the present invention. FIG. 3B is a cross sectional view of the semiconductor device according to the second embodiment of the present invention along the line 3B-3B in FIG. 3A. Points 3Ba, 3Bb, 3Bc, and 3Bd on the line 3B-3B shown in FIG. 3A correspond to division lines 3Ba, 3Bb, 3Bc, and 3Bd of the cross sectional view shown in FIG. 3B, respectively. It should be noted that in FIG. 3A, the plan view is shown through a molded layer 370 to be described below and the layer of the solder resist 260.

The semiconductor device according to the present embodiment shown in FIGS. 3A and 3B is equivalent to the semiconductor device obtained by modifying the semiconductor device shown in FIGS. 2A and 2B according to the first embodiment of the present invention, as described below.

At first, the semiconductor device is manufactured by a method in which the peripheral region is not sealed with the mold resin, such as a method of Over Molded Pad Array Carrier (hereinafter, to be referred to as OMPAC). In this case, to seal the semiconductor chip 210, the mold resin 370 that is formed in the shape of an eight-sided pyramid having a taper in each side of the bottom surface is employed as an example in the present embodiment, instead of the rectangular-parallelepiped mold resin 270 shown in FIG. 2A. As the result, a part of the patch antenna 232 protrudes from the region sealed by the mold resin 370.

Next, the number of layers of the laminate substrate 220 is changed. The laminate substrate 220 according to the present embodiment has first to fourth conductor layers 230A to 230D and first to third insulator layers 240A to 240C. In the laminate substrate 220 according to the present embodiment, the first conductor layer 230A, the first insulator layer 240A, the second conductor layer 230B, the second insulator layer 240B, the third conductor layer 230C, the third insulator layer 240C, and the fourth conductor layer 230D are laminated in this order.

Here, the first conductor layer 230A according to the present embodiment is configured in the same manner as that of the first conductor layer 230A according to the first embodiment of the present invention. In the second conductor layer 230B according to the present embodiment, a ground plane 231 is mainly formed. In the conductor layer 230C according to the present embodiment, a wiring 235 is mainly formed. The fourth conductor layer 230D according to the present embodiment is configured in the same manner as that of the second conductor layer 230B according to the first embodiment of the present invention. The vias 241 according to the present embodiment connect the first and fourth conductor layers 230A and 230D at their ends, and entirely pass through the laminate substrate 220.

It should be noted that it is not necessarily required that all of the above-mentioned changes are combined, and only a part of the changes may be applied to the semiconductor device according to the first embodiment of the present invention. In addition, the other components of the semiconductor device according to the present embodiment are the same as those of the case of the first embodiment of the present invention, and accordingly further detailed description will be omitted.

In case of the OMPAC, the peripheral region not sealed with the mold resin 370 in the semiconductor device has an approximately 1 mm to 2 mm width. However, the peripheral region is also protected by the solder resist 260 as well as the center region sealed with the mold resin 370. Accordingly, it is not necessarily required that a part of or a whole of the metal patch antenna 232 is sealed with the mold resin 370.

Additionally, in the semiconductor device according to the present embodiment, the patch antenna 232 has a portion sealed with the mold resin 370 and a portion protruding from the mold resin 370. Accordingly, a dielectric constant around the patch antenna 232 will be uneven or not uniform. However, by means of arbitrary design before manufacturing or arbitrary adjustment after the manufacturing to be described later in other embodiments, a problem caused by the unevenness of the dielectric constant is avoided. Rather, especially in a high-frequency band such as a millimeter wave, greater advantages can be expected totally in the semiconductor device in improvement of design flexibility of wiring arrangement inside the laminate substrate 220 and in adjustment of antenna characteristics, because the peripheral region of the 1 to 2 mm width can be additionally used to form the patch antenna 232.

Moreover, the patch antenna 232 can be exposed by arbitrarily changing the shapes of the mold resin 370 and the solder resist 260. In this case, the antenna characteristics of the patch antenna 232 becomes hard to receive influence of the mold resin 370 and the solder resist 260, and accordingly it is expected that the design related to wireless communication of the semiconductor device can be made easier.

### Third Embodiment

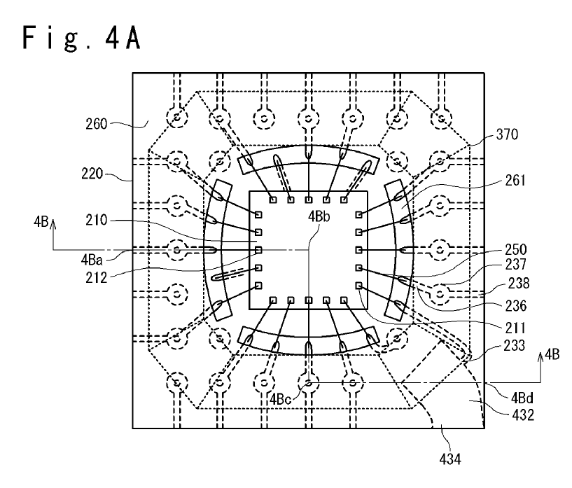

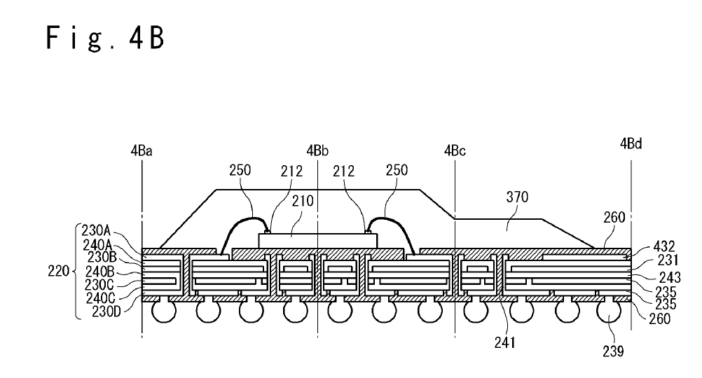

FIG. 4A is a plan view showing a configuration of a semiconductor device according to a third embodiment of the present invention. FIG. 4B is a cross sectional view of the semiconductor device according to the third embodiment of the present invention along the line 4B-4B in FIG. 4A. Points 4Ba, 4Bb, 4Bc, and 4Bd on the line 4B-4B shown in FIG. 4A correspond to division lines 4Ba, 4Bb, 4Bc, and 4Bd of the cross sectional view shown in FIG. 4B, respectively. It should be noted that in FIG. 4A, the layers of the mold resin 370 and the solder resist 260 are made transmissive, as in FIG. 3A.

The semiconductor device according to the present embodiment shown in FIG. 4A and FIG. 4B is equivalent to a semiconductor device obtained by modifying the semiconductor device shown in FIG. 2A and 2B according to the first embodiment of the present invention, as described below. Specifically, the shape of the patch antenna 232 is changed from the typical rectangular shape in which the characteristics can be easily calculated, to a shape which can be used as a mold gate 432 shown in FIG. 4A. In other words, in the present embodiment, the mold gate 432 formed in manufacturing the semiconductor device is applied to the patch antenna 432 after the manufacturing. It should be noted that a tip portion of the mold gate 432 is arranged in an end portion of the laminate substrate 220 as a plated gate 434.

In the semiconductor device according to the present embodiment, a circuit area in the first conductor layer 230A can be saved by using the mold gate 432 as the patch antenna 432.

The shape of the patch antenna 432 according to the present embodiment has a feature as the mold gate. That is, in an example of FIG. 4A, the patch antenna 432 has a portion having a wide width in a rim of the semiconductor device. In addition, the tip portion of the patch antenna 432 perpendicularly contacts to the rim of the semiconductor device. The shape of the mold gate 432 includes a curved line extending from the plated gate 434 to the power supply point 233. The above-mentioned curved line has a possibility to attain that a directivity of the patch antenna 432 can be enlarged.

It should be noted that other components of the semiconductor device according to the present embodiment are the same as those of the first embodiment of the present invention, and accordingly further detailed description is omitted.

### Fourth Embodiment

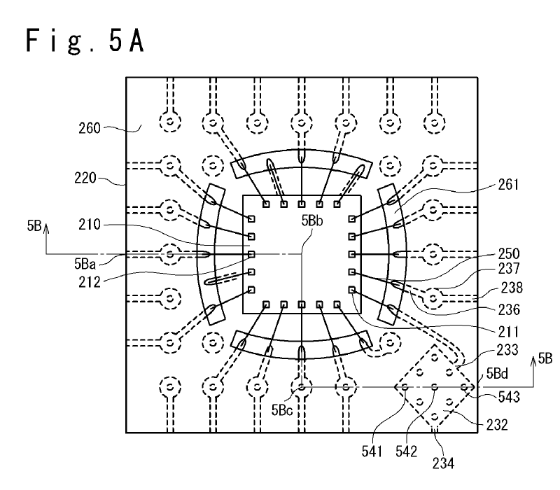

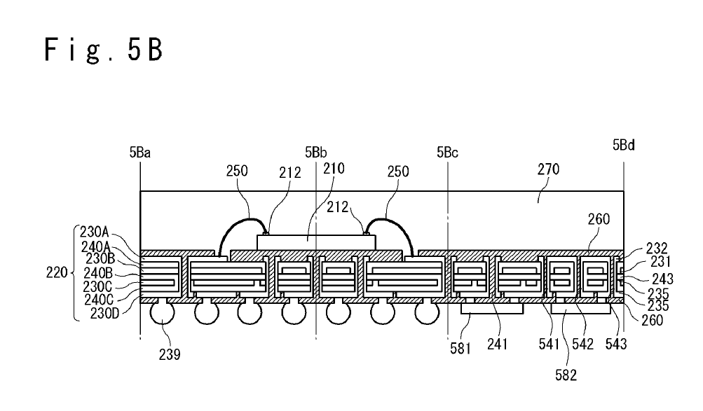

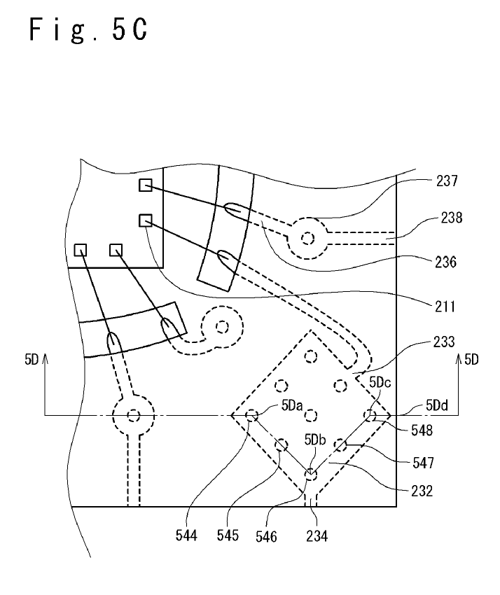

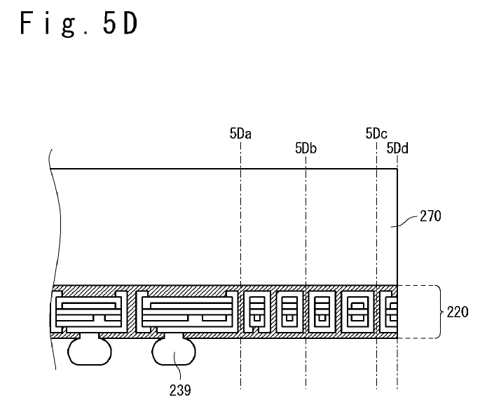

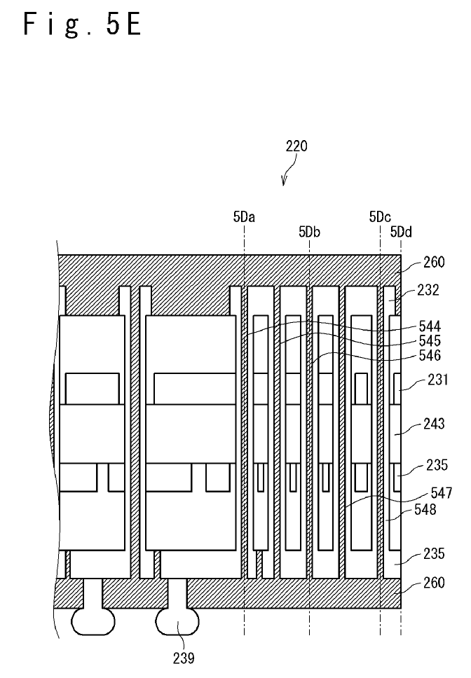

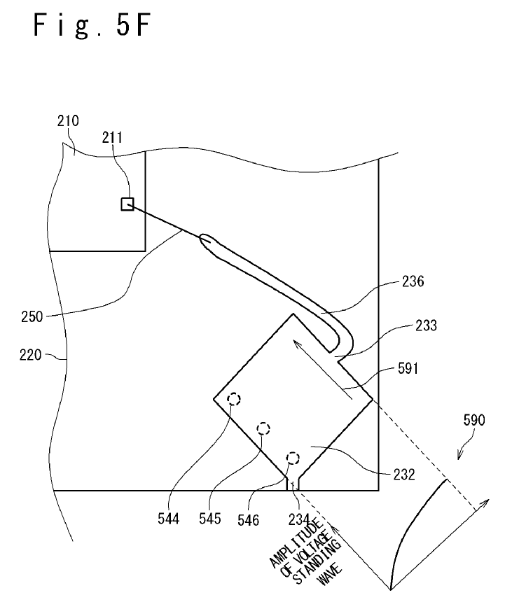

FIG. 5A is a plan view showing a first configuration of a semiconductor device according to a fourth embodiment of the present invention. FIG. 5B is a cross sectional view of the semiconductor device according to the fourth embodiment of the present invention along the line 5B-5B in FIG. 5A. Points 5Ba, 5Bb, 5Bc, and 5Bd on the line 5B-5B shown in FIG. 5A correspond to division lines 5Ba, 5Bb, 5Bc, and 5Bd of the cross sectional view shown in FIG. 5B, respectively. It should be noted that in the plan view of FIG. 5A, the mold resin 270 is omitted from the plan view, and the layer of the solder resist 260 is made transmissive as in the plan view of FIG. 2A.

The semiconductor device according to the first configuration of the present embodiment is equivalent to a semiconductor device obtained by modifying the semiconductor device according to the first embodiment of the present invention shown in FIGS. 2A and 2B, as described below. That is, the configuration of the laminate substrate 220 is the same as that of the second embodiment of the present invention. Next, adjustment vias 541 to 543 for electrically connecting the patch antenna 232 to the wirings in the third or fourth conductor layer 230C or 230D are added. Moreover, impedance elements 581 and 582 are added to change the characteristics of the patch antenna 232.

In the third conductor layer, end portions of the adjustment vias 541 to 543 are connected to the other wirings 235, to allow the characteristics of the patch antenna 232 to be variously adjusted. It should be noted that in FIG. 5B, two adjacent adjustment vias connected by the impedance element are shown as an example. However, the present invention is not limited to this example, and all of or a part of the adjustment vias may be connected to a common ground pattern of the conductor layer 230D through the impedance elements. Here, not only a mere short-circuit wiring but also the impedance elements 581 and 582 such as a resistance, a capacitance, and an inductance may be added to a connecting portion between the adjustment vias 541 to 543 and the other wiring 235, so that the characteristics of the patch antenna 232 can be adjusted in various directions. For this purpose, it is preferred to previously provide many adjustment vias 541 to 543 at a plurality of locations in the patch antenna 232, and to arbitrarily select one of the adjustment vias 541 to 543 through which one of the impedance elements 581 and 582 should be connected to one of the wirings 235.

Here, the attention should be paid to the fact that the addition of the wiring 235 and the impedance elements 581 and 582, that is, the adjustment of the characteristics of the patch antenna 232 can be accomplished to the semiconductor device after the manufacture without disassembling the semiconductor device.

FIG. 5C is a plan view partially showing a second configuration of the semiconductor device according to the fourth embodiment of the present invention. FIG. 5D is a cross sectional view of the semiconductor device according to the fourth embodiment of the present invention in the second configuration along the line 5D-5D in FIG. 5C. FIG. 5E is an enlarged view when the cross sectional view along the line 5D-5D in FIG. 5C showing a second configuration of the laminate substrate 220 according to the fourth embodiment of the present invention is enlarged in a thickness direction. Points 5Da, 5Db, 5Dc, and 5Dd on the section line 5D-5D shown in FIG. 5C correspond to division lines 5Da, 5Db, 5Dc, and 5Dd of the cross sectional views shown in FIGS. 5D and 5E, respectively. It should be noted that in the plan view of FIG. 5C, the mold resin 270 is omitted from the plan view, and the layer of the solder resist 260 is made transmissive as in the plan view of FIG. 2A.

The semiconductor device according to the second configuration of the present embodiment is equivalent to a semiconductor device obtained by modifying the semiconductor device according to the first embodiment of the present invention shown in FIGS. 2A and 2B, as described below. That is, it is supposed that the configuration of the laminate substrate 220 is the same as that of the second embodiment of the present invention. Next, ground vias 544 to 546 are added to electrically connect the patch antenna 232 to the ground plane 231 in the second conductor layer 230B. Moreover, adjustment vias 547 to 548 may be added to electrically connect the patch antenna 232 to the wiring 235 in the third or fourth conductor layer 230C or 230D.

In the semiconductor device according to the second configuration of the present embodiment shown in FIGS. 5C to 5E, one side of the rectangular patch antenna 232 is grounded to the ground plane 231 through the plurality of ground vias 544 to 546 arranged along the side.

An operation of the semiconductor device shown in FIGS. 5C to 5E will be described. FIG. 5F is a diagram partially showing a position relation between the patch antenna 232 and the semiconductor chip 210 according to the second configuration of the fourth embodiment of the present invention and showing an example of a distribution of voltage standing wave obtained by supplying power to the patch antenna 232. FIG. 5F shows a position relation between the semiconductor chip 210, the signal pad 211, the bonding wire 250, the lead line 236, the power supply point 233, the patch antenna 232, the ground vias 544 to 546, the plated line 234, the magnetic current 591, and the laminate substrate 220 which are shown in FIG. 5C. FIG. 5F further shows a graph 590 representing amplitude of voltage standing wave distributed in a width direction of the patch antenna 232.

When power is supplied to the patch antenna 232 arranged as shown in FIG. 5C to FIG. 5F, the voltage standing wave distribution shown in FIG. 5F is obtained. The magnetic current 591 in FIG. 5F appears along one of two sides extending in a direction to the semiconductor chip 210 in the rectangular patch antenna 232. It should be noted that the ground vias 544 to 546 are connected along the other one of the two sides. In addition, the amplitude of voltage standing wave in the graph 590 of FIG. 5F takes a maximum value on the side on which the magnetic current 591 appears, and takes the minimum value on the side to which the ground vias 544 to 546 are connected. This means that, according to the semiconductor device of the present embodiment, even if an area of the patch antenna is not changed, different frequency characteristics from that of the first embodiment of the present invention shown in FIG. 2C can be obtained, as well as a radiation pattern spreading toward a direction in which the radiation is not prevented by the semiconductor chip 210 can be obtained.

In addition, in case of the first configuration of the present embodiment shown in FIGS. 5A and 5B, the adjustment vias 541 and 542 can be grounded through the other vias and wirings even after manufacturing of the semiconductor device. That is, according to the semiconductor device of the present embodiment, adjustment can be realized to further substantially change the characteristics of the patch antenna 232, after the manufacturing of the semiconductor device.

### Fifth Embodiment

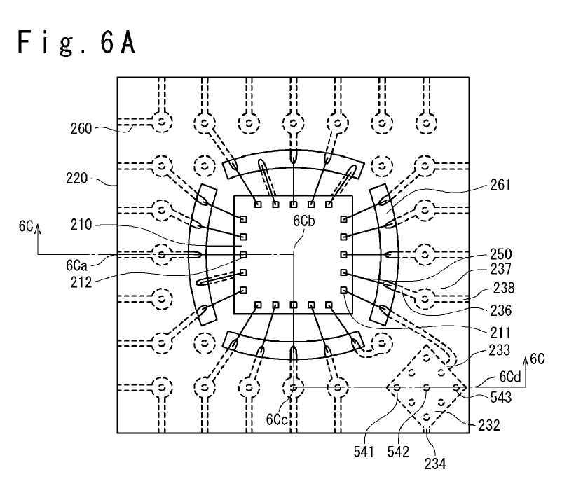

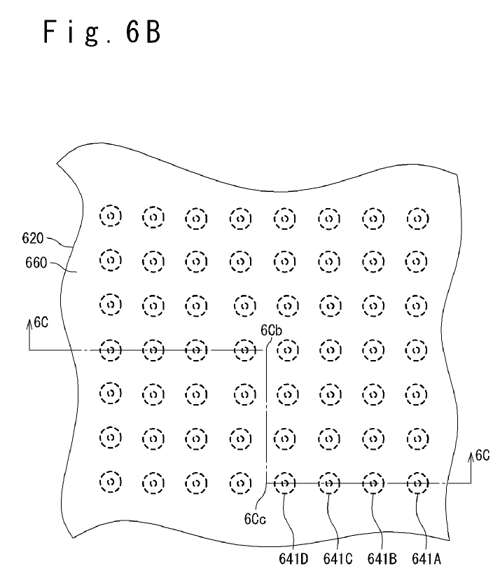

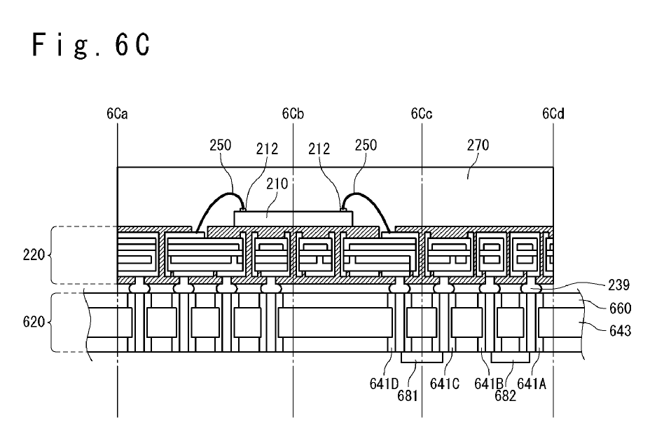

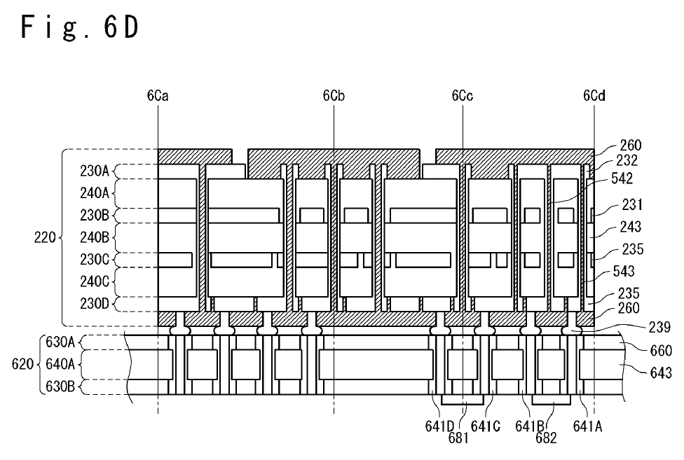

FIG. 6A is a plan view showing a configuration of the semiconductor device according to a fifth embodiment of the present invention. FIG. 6B is a plan view partially showing a configuration of a system board 620 according to the fifth embodiment of the present invention. FIG. 6C is a cross sectional view of the semiconductor device and the system board according to the fifth embodiment of the present invention along the line 6C-6C in FIGS. 6A and 6B. FIG. 6D is an enlarged view when the cross sectional view of the laminate substrate 220 and the system board 620 according to the fourth embodiment of the present invention is enlarged in a thickness direction. Points 6Ca, 6Cb, 6Cc, and 6Cd on the section line 6C-6C shown in FIGS. 6A and 6B correspond to division lines 6Ca, 6Cb, 6Cc, and 6Cd of the cross sectional views shown in FIGS. 6C and 6D, respectively. It should be noted that in the plan view of FIG. 6A, the mold resin 270 is omitted from the plan view and the layer of the solder resist 260 is made transmissive as in the plan view of FIG. 2A.

The semiconductor device according to the present embodiment shown in FIGS. 6A, 6C, and 6D is equivalent to a semiconductor device obtained by modifying the semiconductor device according to the first configuration of the fourth embodiment of the present invention shown in FIGS. 5A and 5B, as described below. That is, in the semiconductor device according to the present embodiment, end portions of the adjustment vias 541 to 543 on the fourth conductor layer 230D side are connected to ball lands 239. Other components of the semiconductor device according to the present embodiment are the same as those of the first configuration according to the fourth embodiment of the present invention shown in FIGS. 5A and 5B, and accordingly further detailed description will be omitted.

Components of the system board 620 according to the present embodiment shown in FIGS. 6B to 6D will be described. The system board 620 includes a first conductor layer 630A, a dielectric layer 640, a second conductor layer 630B, and vias 641A to 641D. Wirings including connection terminal portions of the vias 641A to 641D formed corresponding to arrangement of the ball lands 239 of the semiconductor device according to the present embodiment are provided for the first conductor layer 630A of the system board 620. Wirings including connection terminal portions of the vias 641A to 641D are provided for the second conductor layer 630B of the system board, in the same manner as that of the fourth conductor layer 230D in the semiconductor device according to the fourth embodiment of the present invention. A case where the system board 620 includes two conductor layers 630A and 630B and one dielectric layer 640 will be described here. It should be noted that the total number of these components and features of these components are only an example, and accordingly the present invention is not limited to the example.

A connection relation and a position relation between the components of the system board 620 according to the present embodiment will be described. The first conductor layer 630A, the dielectric layer 640, and the second conductor layer 630B are laminated in this order from the top. The vias 641A to 641D pass through the dielectric layer 640, and electrically connects a terminal portion in the first conductor layer 630A to a terminal portion in the second conductor layer 630B.

A connection between the semiconductor device and the system board 620 according to the present embodiment will be described. In the present embodiment, the semiconductor device is mounted on the system board 620. Specifically, the ball lands 239 in the fourth conductor layer 630D of the semiconductor device are electrically connected to the wirings in the first conductor layer 630A of the system board 620. Accordingly, the adjustment vias 541 to 543 connected to the patch antenna 232 are electrically connected to the wirings of the second conductor layer 630B in the system board 620 through the ball lands 239 in the semiconductor device and the first conductor layer 630A and the vias 641A to 641D in the system board 620.

In this case, various types of devices such as a wiring for short-circuit, a resistance element, a variable resistance element, a capacitance element, a variable capacitance element, and an inductance are arbitrarily added and connected in the second conductor layer 630B of the system board 620, so that the end portions of the adjustment vias 541 to 543, the wirings, and the like in the semiconductor device can be indirectly connected. On the contrary, the connection relation between the adjustment vias 541 to 543 may be released by cutting the wirings provided previously between the adjustment vias 541 to 543. In examples of FIGS. 6C and 6D, the system board 620 further includes two impedance elements 681 and 682. Both ends of the first impedance element 681 are connected to the end portions of two vias 641C and 641D on the second conductor layer 630B side, respectively. Both ends of the second impedance element 682 are connected to the end portions of two vias 641A and 641B on the second conductor layer 630B side, respectively. As the result, the same effect as that of the first configuration according to the fourth embodiment of the present invention shown in FIG. 5B can be obtained. It should be noted that in FIGS. 6C and 6D, two adjacent adjustment vias connected by the impedance element are shown as an example. However, the present invention is not limited to the example, and all of or a part of the adjustment vias may be connected to a common ground pattern of the conductor layer 630B through the impedance element.

According to the present embodiment, the addition of the wiring and the impedance elements 681 and 682, that is, the adjustment of the characteristics of the patch antenna 232 can be accomplished under a condition that the semiconductor device is already mounted on the system board 620.

### Sixth Embodiment

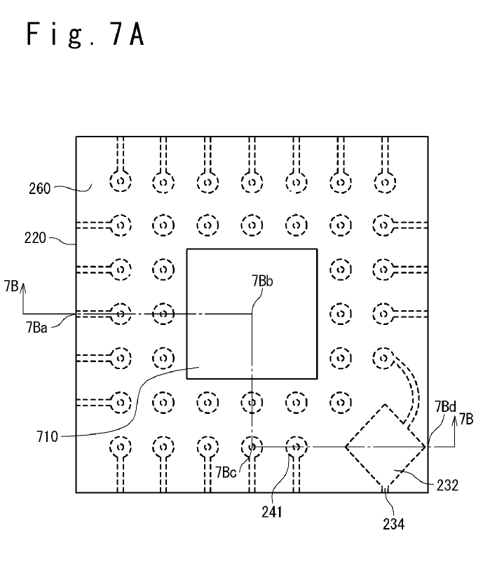

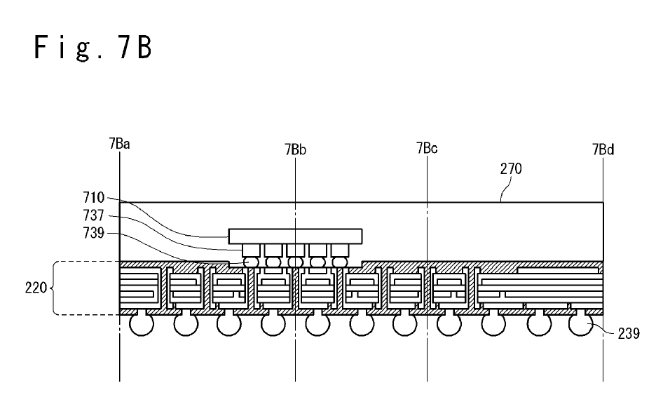

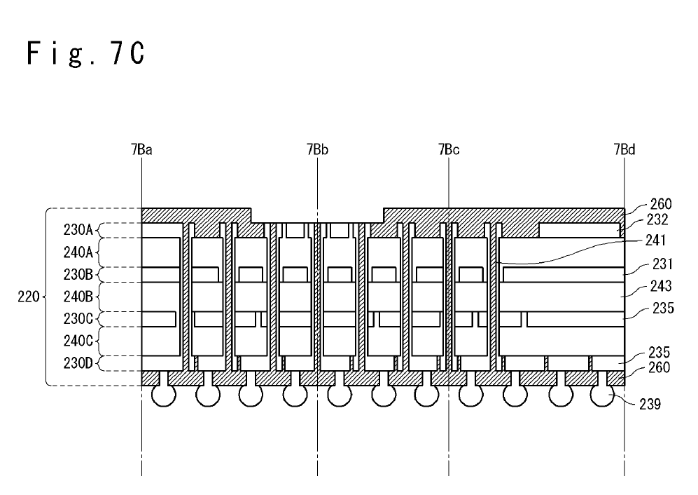

FIG. 7A is a plan view showing a configuration of a semiconductor device according to a sixth embodiment of the present invention. FIG. 7B is a cross sectional view of the semiconductor device according to the sixth embodiment of the present invention along the line 7B-7B in FIG. 7A. FIG. 7C is an enlarged view when the cross sectional view along the line 7B-7B of FIG. 7A showing a configuration of a laminate substrate 220 according to the sixth embodiment of the present invention is enlarged in a thickness direction. Points 7Ba, 7Bb, 7Bc, and 7Bd on the section line 7B-7B shown in FIG. 7A correspond to division lines 7Ba, 7Bb, 7Bc, and 7Bd of the cross sectional views shown in FIGS. 7B and FIG. 7C, respectively. It should be noted that in the plan view of FIG. 7A, the mold resin 270 is omitted from the plan view and the layer of the solder resist 260 is made transmissive, as in the plan view of FIG. 2A.

The semiconductor device according to the present embodiment shown in FIGS. 7A to 7C is equivalent to a semiconductor device obtained by modifying the semiconductor device according to the first embodiment of the present invention shown in FIGS. 2A and 2B, as described below. That is, firstly, the configuration of the laminate substrate 220 is the same as that of the second embodiment of the present invention. Next, instead of the semiconductor chip 210 for the bonding connection according to the first embodiment of the present invention, a semiconductor chip 710 for the flip-chip connection is employed in the present embodiment. In addition, in accordance with the above changes, the wirings in the first conductor layer 630A of the laminate substrate 220 are changed to wirings for the flip-chip mounting.

The semiconductor chip 710 according to the present embodiment includes copper fillers 737 that are pillar conductors formed of copper, and connecting solders 739 provided to the tip of the filler on the element forming surface. The semiconductor chip 710 is mounted on the laminate substrate 220 in the flip-chip connection by use of the connecting solders 739.

The other components of the semiconductor device according to the present embodiment are the same as those of the first embodiment of the present invention, and accordingly further detailed description is omitted.

In the first embodiment and so on of the present invention, the bonding wire 250 for connecting the semiconductor chip 210 to the patch antenna 232 on the laminate substrate interferes with adjacent other bonding wires 250, and there is a risk of generating a crosstalk noise. According to the semiconductor device of the present embodiment, influence of the crosstalk noise can be reduced.

### Seventh Embodiment

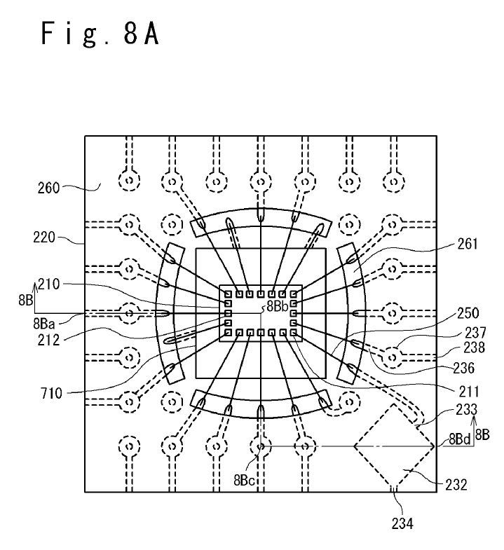

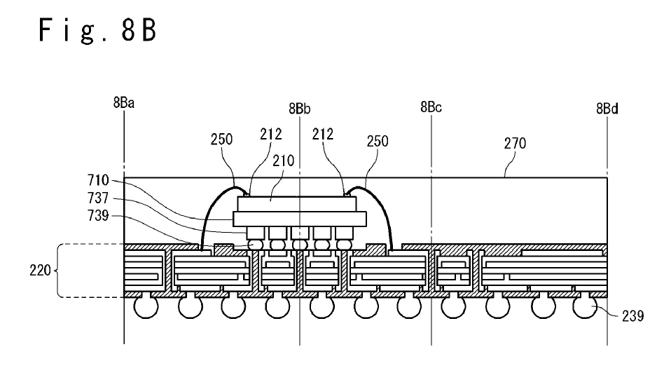

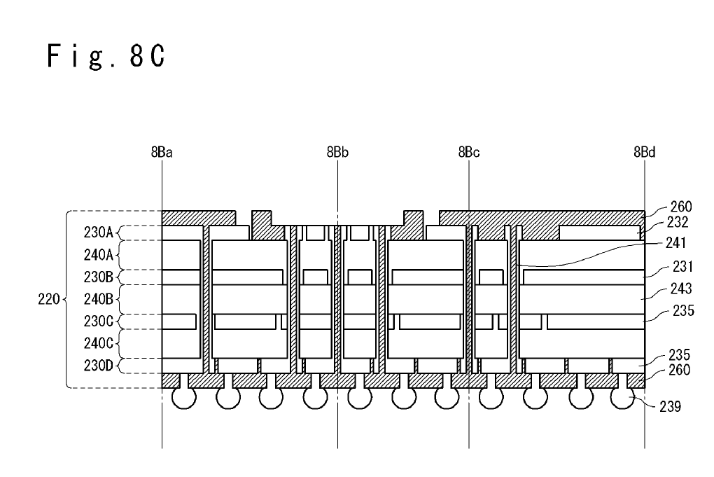

FIG. 8A is a plan view showing a configuration of a semiconductor device according to a seventh embodiment of the present invention. FIG. 8B is a cross sectional view of the semiconductor device according to the seventh embodiment of the present invention along the line 8B-8B in FIG. 8A. FIG. 8C is an enlarged view when the cross sectional view at the section line 8B-8B in FIG. 8A showing a configuration of a laminate substrate 220 according to the seventh embodiment of the present invention is enlarged in a thickness direction. Points 8Ba, 8Bb, 8Bc, and 8Bd on the line 8B-8B shown in FIG. 8A correspond to division lines 8Ba, 8Bb, 8Bc, and 8Bd of the cross sectional views shown in FIGS. 8B and 8C, respectively. The semiconductor device according to the present embodiment shown in FIGS. 8A to 8C is equivalent to a semiconductor device obtained by modifying the semiconductor device according to the first embodiment of the present invention shown in FIGS. 2A and 2B, as described below. That is, firstly, the configuration of the laminate substrate 220 is the same as that of the second embodiment of the present invention. Next, in addition to the first semiconductor chip 210 for sending and receiving a signal to and from the patch antenna, the semiconductor device according to the present embodiment further includes another second semiconductor chip 710.

Here, a case where the semiconductor device has two semiconductor chips 210 and 710, and further the first semiconductor chip 210 is mounted on the second semiconductor chip 710 will be described. However, the number and types of the semiconductor chips 210 and 710 and their position relation are only one example, and accordingly the present invention is not limited to the example. Moreover, a combination of the first and second semiconductor chips 210 and 710 may be a semiconductor chip for RF (Radio Frequency) and a semiconductor chip for logic calculation, may be a semiconductor chip for analog signal and a semiconductor chip for digital signal, may be a silicone semiconductor chip and a gallium arsenide semiconductor chip, and both of the semiconductor chips may be a type to be connected in a bonding connection.

In the semiconductor device according to the present invention shown in FIGS. 8A to 8C, a configuration of a portion related to the flip-chip connection between the second semiconductor chip 710 and the laminate substrate 220 is the same as that of the sixth embodiment of the present invention shown in FIGS. 7A and 7B. In the semiconductor device according to the present invention shown in FIGS. 8A to 8C, configurations of the other components are the same as those of the first embodiment of the present invention shown in FIGS. 2A and 2B. Accordingly, further detailed description of the configurations of the semiconductor device according to the present embodiment shown in FIGS. 8A to 8C will be omitted.

In an example shown in FIG. 8A to FIG. 8C, when being mounted on the second semiconductor chip 710, the first semiconductor chip 210 is arranged on an approximately center position of the second semiconductor chip 710. This is a result from preferentially considering reduction of influence caused by deformation of the semiconductor device as a whole, and the present invention is not limited to this choice. Giving priority to save the bonding wire 250, the first semiconductor chip 210 may be arranged on one end portion of the second semiconductor chip 710, for example.

It should be noted that it is generally better in terms of noise reduction that a path between the semiconductor chip and the patch antenna is short, and accordingly the first semiconductor chip 210 connected to the patch antenna 232 may be arranged under the second semiconductor chip 710. As shown in FIGS. 8A to 8C as an example, when the first semiconductor chip 210 is arranged on the second semiconductor chip 710, the bonding wires 250 become longer in comparison with a case where the first semiconductor chip 210 is arranged under the second semiconductor chip 710. However, at this time, the characteristics of the patch antenna 232 can be adjusted intensively to increase impedance.

Furthermore, in case of a semiconductor device in which another third semiconductor chip is stacked, the first semiconductor chip 210 may be arranged between the second and third semiconductor chips. In these cases, in order to suppress the influence of crosstalk noise, the bonding wire 250 which mediates the connection between the first semiconductor chip 210 and the patch antenna 232 is desired to have a different profile from those of other bonding wires connected to the second or third semiconductor chip. For example, the bonding wire 250 mediating the connection between the first semiconductor chip 210 and the patch antenna 232 is extended to the longest length in comparison with the lengths of other bonding wires, and a distance from the bonding wire 250 to the laminate substrate 220 at a point where the distance between the bonding wire 250 and the laminate substrate 220 becomes the maximum distance is set to be higher than those of other bonding wires. In this case, the influence of crosstalk noise can be suppressed based on difference of loop profiles between the bonding wire 250 and other bonding wires. The converse case is equivalently true, and accordingly, even if the bonding wire 250 has the shortest length and the distance to the laminate substrate 220 is the minimum distance, the same effect can be obtained.

In the above description, the case where a plurality of semiconductor chips included in the same semiconductor device are vertically laminated will be described. However, a part of or all of the plurality of semiconductor chips may be arranged along a plan direction on the laminate substrate.

### Eighth Embodiment

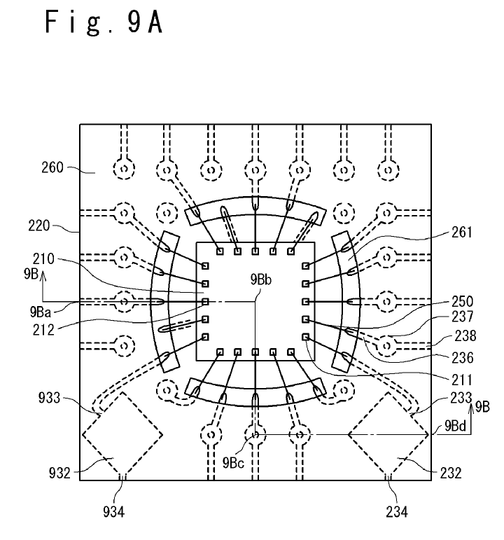

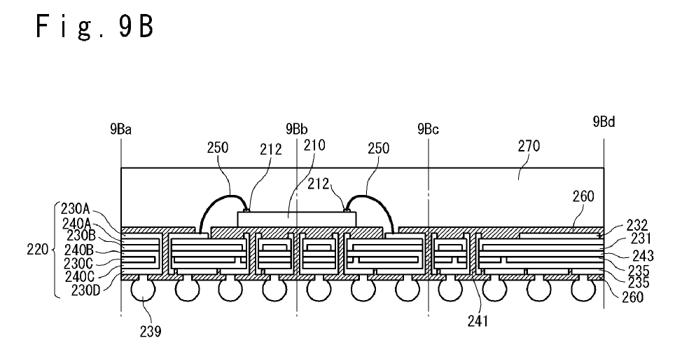

FIG. 9A is a plan view showing a configuration of a semiconductor device according to an eighth embodiment of the present invention. FIG. 9B is a cross sectional view of the semiconductor device according to the eighth embodiment of the present invention along the line 9B-9B in FIG. 9A. Points 9Ba, 9Bb, 9Bc, and 9Bd on the section line 9B-9B shown in FIG. 9A correspond to division lines 9Ba, 9Bb, 9Bc, and 9Bd of the cross sectional view shown in FIG. 9B, respectively. It should be noted that in the plan view of FIG. 9A, the mold resin 270 is omitted from the plan view and the layer of the solder resist 260 is made transmissive, as in the plan view of FIG. 2A.

The semiconductor device according to the eighth embodiment of the present invention shown in FIGS. 9A and 9B is equivalent to a semiconductor device obtained by modifying the semiconductor device according to the first embodiment of the present invention shown in FIGS. 2A and 2B, as described below. That is, firstly, the configuration of the laminate substrate 220 is the same as that of the second embodiment of the present invention. Next, the semiconductor device according to the present embodiment further includes a second patch antenna 932, a second power supply point 933, and a second plated line 934. The second patch antenna 932 is connected to the semiconductor chip 210 through the second power supply point 933, another lead line 236, another bonding wire 250, and another signal pad 211 in the same manner as those of the first patch antenna 232. When the semiconductor chip 210 supplies power independently from or in synchronization with the first and second patch antennas 232 and 932, the first and second patch antenna 232 and 932 are able to emit a radio signal independently or synchronously.

The other components of the semiconductor device according to the present embodiment are the same as those of the first embodiment of the present invention, and accordingly further detailed description will be omitted.

Here, the number of the patch antenna is two, but the number is just an example. Accordingly, the present invention is not limited to the example, and the number of the patch antennas may be much larger. In addition, the plurality of patch antennas may operate independently from each other, and may operate as a synchronized adaptive array antenna.

The features of the semiconductor device according to the above-described embodiments of the present invention can be arbitrarily combined within a technically consistent scope.

Although the present invention has described above in connection with several (exemplary) embodiments thereof, it would be apparent to those skilled in the art that those (exemplary) embodiments are provided solely for illustrating the present invention, and should not be relied upon to construe the appended claims in a limiting sense.

What is claimed is:

1. A semiconductor device comprising:
a semiconductor chip;
a substrate used to mount said semiconductor chip;
an antenna formed on said substrate and configured to radiate a signal outputted from said semiconductor chip; and
resin configured to cover said antenna,
wherein said substrate comprises a mounting section used to be mounted on another substrate

2. The semiconductor device according to claim 1, wherein said mounting section comprises solder lands connected to said another substrate.

3. The semiconductor device according to claim 1, wherein said resin seals said semiconductor chip, said substrate and at least a part of said antenna to suppress a warp through conjunction of said semiconductor chip and said substrate and a transformation of said substrate.

4. The semiconductor device according to claim 3, wherein said resin comprises metallic oxide equal to or more than 85% weight %.

5. The semiconductor device according to claim 1, wherein said substrate further comprises vias formed in a thickness direction of said substrate and connected with a circuit formed on said substrate, and
wherein said vias comprises via lands formed on a same surface of said substrate as said mounting section and used to change circuit characteristics by changing connection relation after manufacture.

6. The semiconductor device according to claim 5, wherein said vias comprises an adjustment via connected with said antenna and configured to change a characteristic of said antenna by changing the connection relation of said via lands after the manufacture.

7. The semiconductor device according to claim 5, wherein said substrate further comprises a grounded ground plane, and
wherein said vias comprises ground vias used to connect said antenna and said ground plane.

8. The semiconductor device according to claim 1, wherein said antenna is arranged in a corner section of said substrate such that said semiconductor chip does not hinder a radiation pattern of said antenna.

9. The semiconductor device according to claim 1, wherein said antenna comprises a planar antenna.

10. The semiconductor device according to claim 1, wherein said antenna comprises a linear antenna.

11. The semiconductor device according to claim 1, wherein said antenna is plural.

12. The semiconductor device according to claim 1, further comprising a bonding wire configured to connect a pad of said semiconductor chip and a pad of said substrate.

13. The semiconductor device according to claim 1, wherein said substrate further comprises another mounting section used to perform a flip chip connection said semiconductor chip.

14. The semiconductor device according to claim 13, further comprising:
said another semiconductor chip stacked on said semiconductor chip; and
a bonding wire configured to connect a pad of said another semiconductor chip and a pad of said substrate.

15. The semiconductor device according to claim 1, further comprising a shield configured to protect said semiconductor chip and said substrate,
wherein at least a part of said antenna is exposed from said shield.
